(19) United States
(12) Patent Application Publication
(10) Pub. No.: US 2010/0195657 A1
(43) Pub. Date: Aug. 5, 2010

(54) METHOD AND SYSTEM FOR SELF-ROUTING IN SYNCHRONOUS DIGITAL CROSS-CONNECTION

(76) Inventors: Jing Wang, Shenzhen (CN); Zhiwei Zhang, Shenzen (CN); Chunsong Deng, Shenzhen (CN)

Correspondence Address: CLARK & ELBING LLP, 101 FEDERAL STREET, BOSTON, MA, 02110, US

(21) Appl. No.: 12/678,660

(22) PCT Filed: Dec. 29, 2007
(86) PCT No.: PCT/CN07/03976

§ 371 Date: Mar. 17, 2010

(30) Foreign Application Priority Data
Sep. 20, 2007 (CN) 200710122073.8

(51) Int. Cl. H04L 12/56; H03M 13/09; G06F 11/10

(52) U.S. Cl. 370/392; 714/807; 714/819; 714/E11.032

(57) ABSTRACT

The present invention discloses a method for self-routing in synchronous digital cross-connection, comprising: self-routing transmitting means insert a CM data into a STM-N data stream according to a frame header indicator and a self-routing start address signal; self-routing receiving means extract the CM data from the STM-N data stream according to the frame header indicator and the self-routing start address signal, and write the CM data into a cross-connection control memory. The present invention also discloses a system for self-routing in synchronous digital cross-connection, comprising: self-routing transmitting means and self-routing receiving means, wherein, the self-routing transmitting means comprise a self-routing transmitting control unit, a first CRC checking unit and an inserting data generating unit, the self-routing receiving means comprise a self-routing extracting control unit, a second CRC checking unit and a cross-connection control memory. The present invention provides users with a self-routing scheme for synchronous digital cross-connection, which can be realized with ease, occupies less resource, has better reliability and is suitable for large capacity cross configuration.

### FIELD OF THE INVENTION

The present invention relates to digital communication field, in particular to a method and a system for self-routing in synchronous digital cross-connection.

### BACKGROUND OF THE INVENTION

A cross-connection device is an important part of an optical Synchronous Digital Hierarchy (SDH) system. Synchronous digital cross-connection realizes the transparent connection and the reconnection among a plurality of Virtual Containers (VC) formed in accordance with the Standard G.709. The transparent connection and the reconnection are controllable between any ports. Besides the SDH rates defined by the Standard 6707 and the Plesiochronous Digital Hierarchy (PDH) rates defined by the Standard G.702, these ports can also support control and management function defined by the SDH management standard G.784.

The grooming of the inter-layer traffic and the combination of the intra-layer traffic are one important aspect of the management of the cross-connection device. Wherein, the grooming of the inter-layer traffic is to groom a lower order path into a specific higher order path in accordance with service categories, destinations, or protection categories, and to enable these paths to be managed respectively. Likewise, a higher order path may also be groomed into a Synchronous Transport Module-N (STM-N) data stream. The combination of the intra-layer traffic is a process for improving service of a service layer, which combines a user connection from a service layer path into a service layer path with less service so as to enhance the utilization rate of the system or the device.

According to the types of the cross-connection, cross-connection devices can be divided into two categories, i.e., cross-connection devices for providing a higher order VC and cross-connection devices for providing a lower order VC. A cross-connection device for executing a higher order VC usually connects two or more STM-N data streams, wherein the STM-N data streams must be adjusted to the reference clock of the cross-connection device, and the pointers of the STM-N data streams are adjusted correspondingly. If the STM-N data streams are inserted into an Administration Unit (AU), synchronous cross-connection may be carried out on the STM-N data streams in a single space-division switching matrix, and the synchronous adjustment of the STM-N data streams ensures the non-invasive rearrangement in the matrix. A VC-3 or a VC-4 switching matrix with very big capacity is formed in this way. The cross-connection function of a lower order VC is similar to that of a higher order VC, except that the VC-3 is substituted by a lower order VC. A cross-connection relation may be established between a specific input end and a specific output end through configuring a cross matrix.

At the present time, a conventional method for determining a cross matrix of the cross-connection relation is that a network administrator configures a cross-connection chip through a processor interface. However, this method requires to occupy the system resources of the processor, and under an application environment where the cross capacity is very large and the cross matrix of the chip needs to be updated quickly, the self-routing configuration method using a processor can not satisfy the demand in practice.

### SUMMARY OF THE INVENTION

In view of the problem mentioned above, the present invention provides a method and a system for self-routing in synchronous digital cross-connection. The method and the system provide users with a self-routing scheme for synchronous digital cross-connection, which can be realized with ease, occupies less system resources, has high reliability and is suitable for large capacity cross configuration.

The present invention provides a method for self-routing in synchronous digital cross-connection, comprising:

A. self-route transmitting means insert a cross-connection control memory (CM) data into a STM-N data stream according to a frame header indicator and a self-routing start address signal;

B. self-routing receiving means extract the CM data from the STM-N data stream according to the frame header indicator and the self-routing start address signal; and

C. the self-routing receiving means write the CM data into a cross-connection control memory.

Step A of the method further comprises:

the self-routing transmitting means perform cyclic redundancy check (CRC) on the CM data to be inserted into the STM-N data stream to obtain a first check value, and insert the first check value into the STM-N data stream;

Step B of the method further comprises: the self-routing receiving means extract the first check value from the STM-N data stream;

Step C of the method is:

the self-routing receiving means perform CRC check on the CM data extracted from the STM-N data stream to obtain a second check value, and compare the second check value with the first check value extracted from the STM-N data stream: if the second check value is the same as the first check value, the CM data will be written into the cross-connection control memory; otherwise, the CM data will not be written into the cross-connection control memory.

Step A of the method further comprises:

the self-routing transmitting means set a configuration allowance signal, and insert the configuration allowance signal into the STM-N data stream;

Step B of the method further comprises: the self-routing receiving means extract the configuration allowance signal from the STM-N data stream;

the Step C of the method is:

the self-route receiving means analyze the configuration allowance signal extracted from the STM-N data stream, and if the configuration allowance signal is valid, the CM data will be written into the cross-connection control memory; otherwise, the CM data will not be written into the cross-connection control memory.

Prior to Step A, the method further comprises:

the self-routing transmitting means set self-routing parameters which comprise a self-routing insertion position; and

the self-routing transmitting means insert the CM data into the STM-N data stream according to the self-routing insertion position.

The self-routing parameters of the method further comprise a self-routing configuration page change request indicator;

the cross-connection control memory of the method comprises an active page and an inactive page;

the self-routing receiving means of the method switch between the active pages and the inactive pages according to the self-route configuration page change request indicator, and write the CM data into the inactive pages.

The present invention further provides a system for self-routing in synchronous digital cross-connection, comprising:

self-routing transmitting means, configured to insert a CM data into a STM-N data stream according to a frame header indicator and a self-routing start address signal; and

self-routing receiving means, configured to extract the CM data from the STM-N data stream according to the frame header indicator and the self-routing start address signal and to write the CM data into a cross-connection control memory.

The self-routing transmitting means of the system comprise a self-routing transmitting control unit, a first CRC checking unit and an inserting data generating unit, wherein,

the first CRC checking unit, is configured to perform CRC check on the CM data to be inserted into the STM-N data stream to obtain a first check value; and

the inserting data generating unit, is configured to insert the first check value and the CM data into the STM-N data stream under the control of the self-routing transmitting control unit;

the self-routing receiving means of the system comprise a self-routing extracting control unit, a second CRC checking unit and a cross-connection control memory, wherein,

the second CRC checking unit, is configured to perform CRC check on the CM data extracted from the STM-N data stream to obtain a second check value, and to compare the second check value with the first check value extracted from the STM-N data stream: if the second check value is the same as the first check value, the self-routing extracting control unit will write the CM data into the cross-connection control memory; otherwise, the self-routing extracting control unit will not write the CM data into the cross-connection control memory.

The self-routing transmitting control unit of the system sets a configuration allowance signal, and the inserting data generating unit inserts the configuration allowance signal into the STM-N data stream;

the self-routing extracting control unit of the system analyzes the configuration allowance signal extracted from the STM-N data stream, and if the configuration allowance signal is valid, the CM data will be written into the cross-connection control memory; otherwise, the CM data will not be written into the cross-connection control memory.

The present invention further provides a self-routing transmitting device in synchronous digital cross-connection, comprising:

a self-routing transmitting control unit, a first CRC checking unit and an inserting data generating unit, wherein,

the first CRC checking unit performs CRC check on the CM data to be inserted into a STM-N data stream to obtain a first check value, and the inserting data generating unit inserts the first check value and the CM data into the STM-N data stream under the control of the self-routing transmitting control unit.

The present invention further provides a self-routing receiving device in synchronous digital cross-connection, comprising:

a self-routing extracting control unit, a second CRC checking unit and a cross-connection control memory, wherein,

the self-routing extracting control unit extracts a CM data from a STM-N data stream; the second CRC checking unit performs CRC check on the CM data to obtain a second check value, and compares the second check value with the first check value extracted from the STM-N data stream: if the second check value is the same as the first check value, the self-routing extracting control unit will write the CM data into the cross-connection control memory; otherwise, the self-routing extracting control unit will not write the CM data into the cross-connection control memory.

The method and the system for self-routing in synchronous digital cross-connection provided in the present invention process the cross configuration of each VC through an upstream service board of the STM-N data stream and transmit it to a cross chip, and the cross chip performs self-routing configuration in accordance with the received cross configuration information of each VC, so that the problem in the art that a processor interface can hardly satisfy the demand on large capacity cross-connection configuration can be overcome, and beneficial effect can be achieved to provide users with a self-routing scheme for synchronous digital cross-connection, which can be realized with ease, occupies less system resources, has high reliability and is suitable for large capacity cross configuration.

### BRIEF DESCRIPTION OF THE DRAWINGS

FIG. 1 is a block diagram of the system for self-routing in synchronous digital cross-connection according to the present invention;

FIG. 2 is a position distribution diagram of the self-routing overhead in synchronous digital cross-connection according to the present invention;

FIG. 3 is a schematic diagram of the self-routing data format in synchronous digital cross-connection according to the present invention;

FIG. 4 is a structure block diagram of the self-routing transmitting means in synchronous digital cross-connection according to the present invention; and

FIG. 5 is a structure block diagram of the self-routing receiving means in synchronous digital cross-connection according to the present invention.

### DETAILED DESCRIPTION OF EMBODIMENTS

The present invention will be described hereinafter in detail in conjunction with the drawings thereof, taking the VC-4 space-division cross-connection for example.

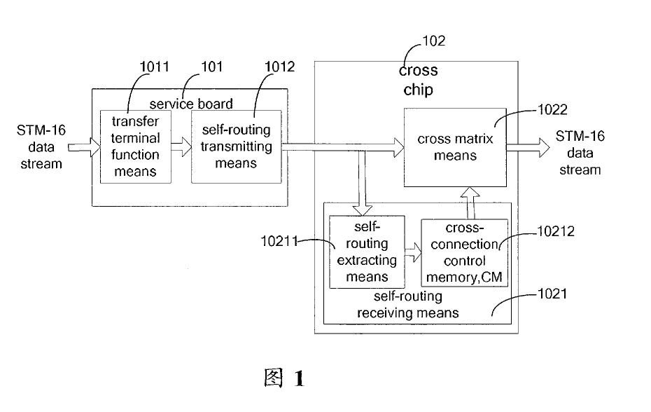

FIG. 1 is the block diagram of the system for self-routing in synchronous digital cross-connection according to the present invention, including: a service board 101 and a cross chip 102, wherein, the service board 101 comprises a transfer terminal function means 1011 and a self-routing transmitting means 1012, and the cross chip 102 comprises a self-routing receiving means 1021 and a cross matrix means 1022, wherein the self-routing receiving means 1021 comprises a self-routing extracting means 10211 and a cross-connection control memory 10212.

After the service board 101 finishes the processing in the transfer terminal function means 1011, when the system control needs to configure a self-routing mode, the self-routing transmitting means 1012 sets a start address of self-routing, i.e., the position for inserting the self-routing in the overhead, and simultaneously performs a Cyclic Redundancy Check (CRC) on the CM data to be transmitted downwards and inserts both the check value and the CM data into the position of an overhead byte corresponding to the self-routing in a STM-16 frame structure, and then transmits it to the cross chip 102.

The cross chip 102 receives the STM-16 data stream transmitted by the service board 101. According to the status information of the self-routing mode configured by the system, the self-routing receiving means 1021 extracts the CRC check value and the CM data from a preset position of the overhead byte corresponding to the self-routing, and performs the CRC check. If the check result is correct, the corresponding contents of the CM are rewritten, and the configuration on the cross matrix means 1022 is accomplished.

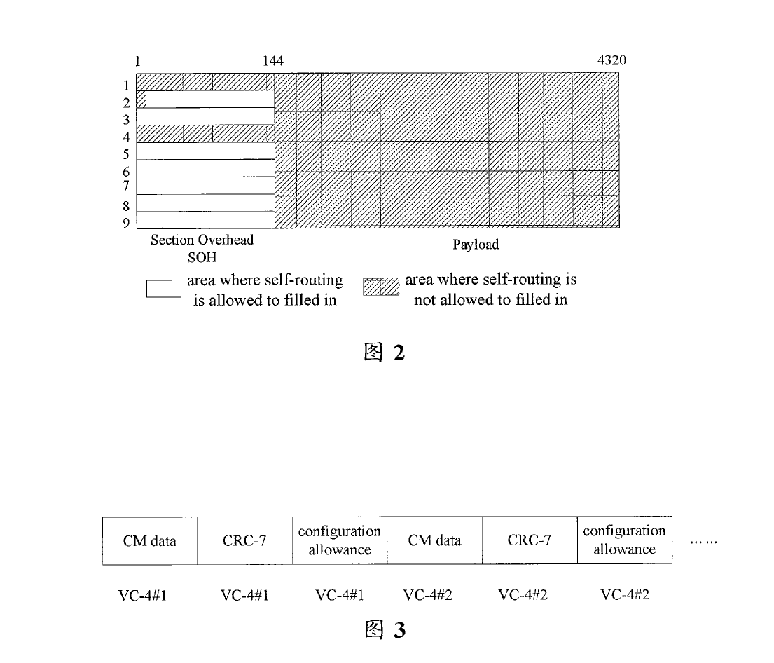

FIG. 2 is a position distribution diagram of the self-routing overhead in synchronous digital cross-connection according to the present invention, and, taking the STM-16 frame structure for example, FIG. 2 illustrates the bytes allowing the transmission of the self-routing information in the STM-16 frame structure. The area with oblique lines in this figure indicates that the transmission of the self-routing information is not allowed in this area, while the blank area indicates that transmission of the self-routing information can be allowed in this area. Seen from this figure, the payload byte position cannot be used for the transmission of the self-routing information, and in principle, the transmission of the self-routing information can be allowed in the Section Overhead (SOH) byte position except for the frame header bytes in Line 1, the pointer bytes in Line 4, and the B1 bytes in Line 2 of Column 1. In the implementing of the present invention, the self-routing position and the data distribution characteristics can be set in accordance with users' needs. The overhead bytes of other frame structures are different, however, the allowable areas for the distribution of the self-routing position are similar, i.e., the transmission of the self-routing information is not allowed in the payload position or the frame header bytes in Line 1 and the pointer bytes in Line 4 in the Section Overhead.

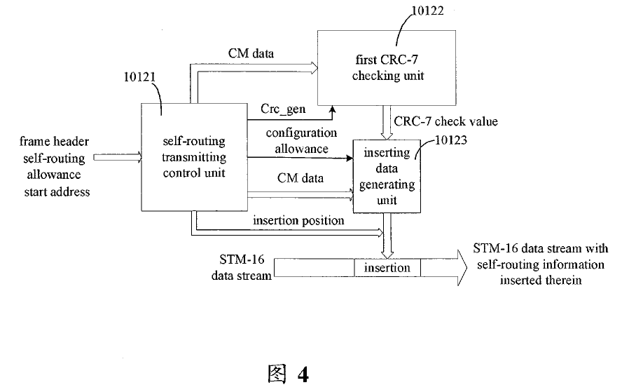

FIG. 3 is a schematic diagram of the self-routing data format in synchronous digital cross-connection according to the present invention, i.e., the definition of the self-routing information format to be transmitted. In order to avoid errors in the CM configuration data of a cross matrix caused by the error codes in the self-routing information in the transmission process of the self-routing information, the CRC-7 check method is used in the self-routing information format, i.e., the transmitting side transmits the self-routing information along with a CRC-7 check code. If the receiving side finds that the CRC-7 check is incorrect, it will refuse to receive the CM data. At the same time, a configuration allowance bit is set to be transmitted along with each CM data. If the bit is not allowed, the CM data will not be received even if the CRC-7 check is correct, which, thereby, makes the control of the self-routing configuration more flexible. The self-routing information illustrated in FIG. 3 is sequentially transmitted in accordance with the serial numbers of the VC-4. If the complete self-routing information cannot be transmitted in one line of the overhead position, another line must be used, i.e., the transmission of the self-routing information must be temporarily interrupted at the position of the payload, and is restarted in the next line in the area where the transmission of the self-routing is allowed. If the transmission cannot be finished in the next line, the transmission of the self-routing information will be continued in a further next line. In order to make the transmission process of the self-routing information of the CM more stable and reliable, in practical operating process, the system may repeatedly transmit the self-routing information of the same CM in accordance with the amount of the self-routing information to be transmitted. Thus, when errors appear in transmitting the self-routing information of a certain CM for the first time, the probability that errors occur in transmitting the self-routing information of the CM for the second time is comparatively low, so the success rate in configuring the CM is greatly improved.

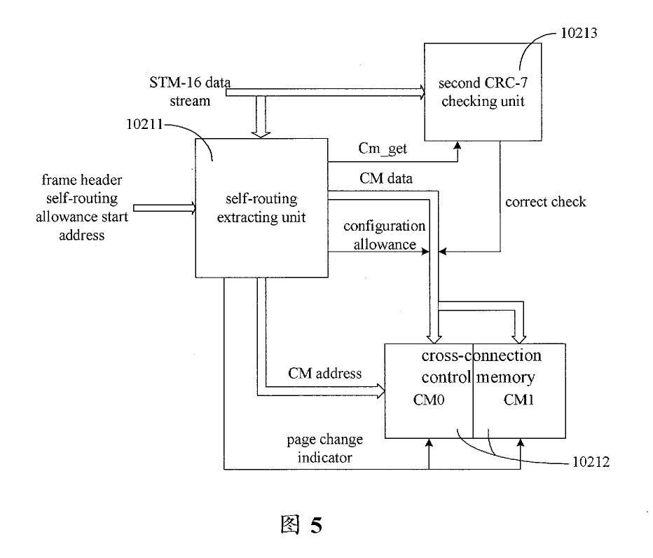

FIG. 4 is a structure block diagram of the self-routing transmitting means 1012 in synchronous digital cross-connection according to the present invention. FIG. 5 is a structure block diagram of the self-routing receiving means 1021 in synchronous digital cross-connection according to the present invention. These two means can be set uniformly and used together.

In FIG. 4, the self-routing transmitting means 1012 comprises a self-routing transmitting control unit 10121, a first CRC-7 checking unit 10122 and an inserting data generating unit 10123.

The self-routing transmitting control unit 10121 sets, in accordance with the self-routing position distribution diagram as shown in FIG. 2, self-routing parameters, and inserts the self-routing information into the STM-16 data stream according to the self-routing parameters. The self-routing parameters include a self-routing insertion position, the number of the self-routing insertion, and a page change request indicator after completing the self-routing configuration. After finishing operations such as pointer processing and frame header alignment, the STM-16 data stream in FIG. 4 enters the self-routing transmitting means 1012. Wherein, a frame header indicator denotes the frame header position of the STM-16 data stream, a self-routing start address signal denotes the insertion start position of self-routing in the frame structure, and the frame header indicator and self-routing start address signal together determine the position of the self-routing information of each CM of the VC-4 in the SOH of the frame structure. The self-routing transmitting control unit 10121 determines, according to the signals such as the frame header and the self-routing start address signal, the time when the self-routing information should be inserted, and transmits the CM data and a CRC-7 check enable signal crc_gen to the first CRC-7 checking unit 10122. The first CRC-7 checking unit 10122 produces, according to the CM data and the first CRC-7 check enable signal crc_gen, a CRC-7 check value, and the inserting data generating unit 10123 inserts, according to the self-routing data format as shown in FIG. 3, the CRC-7 check value, the CM data, and the configuration allowance signal into the corresponding positions of self-routing information of each CM in the SOH. After configuration of all the CM information is accomplished, the self-routing transmitting control unit 10121 needs to insert a page change indicator, which can be defined by a user, at the subsequent self-routing allowance position. In the process, B1 byte needs to be recreated before transmitting the STM-16 data stream which has been inserted with the self-routing information.

In FIG. 5, the self-routing receiving means 1021 comprises a self-routing extracting control unit 10211, a second CRC-7 checking unit 10213, and a cross-connection control memory 10212.

The self-routing extracting control unit 10211 determines, according to the signals such as the frame header and the self-routing start address signal, the time when the self-routing information arrives, i.e., corresponding to the position of the self-routing information in the STM-16 data stream, and produces a self-routing extracting indication signal cm_get to transmit to the second CRC-7 checking unit 10213. The second CRC-7 checking unit 10213 extracts, according to the self-routing extracting indication signal cm_get, the self-routing information from the STM-16 data stream, and performs the CRC-7 check on the CM data in the self-routing information. If the CRC-7 check result is the same as the received CRC-7 check result, the check is correct, and if at this time, the configuration allowance signal is valid, the CM data will be written into the inactive pages of corresponding CM. Further, if, at this time, the self-routing extracting control unit 10211 detects a page change indicator, switch will occur between the current active page and an inactive page. The cross-connection control memory 10212 comprises two parts, i.e. CM0 and CM1, wherein, when the CM0 is on the current active page, the CM1 is on the inactive page; otherwise, when the CM1 is on the current active page, the CM0 is on the inactive page.

In the present invention, in order to ensure that the page change operation is performed only after each VC-4 in the STM-16 data stream is correctly configured with the CM data, the self-routing receiving means sets a status signal for each VC-4 indicating whether it has been configured or not. As long as there is a CM inactive page in a VC-4, the content of which has not been rewritten in the configuration process, the signal is in a low state, and even if a page change indicator is received, the page change operation is not performed, so that it can be avoided that the cross-connection of some VC-4 are not updated correctly after the pages are changed. However, the case is excluded if it has not been rewritten because the configuration allowance bit corresponding to the VC-4 is invalid.

In the method and system for self-routing in cross-connection of the present invention, in pre-stage service processing, the CM data of the cross matrix information to be configured is inserted into a predefined overhead byte position in the STM-N data stream, the cross-connection chip extracts the CM value from the overhead byte position corresponding to the STM-N data stream, and rewrites the corresponding CM in the cross matrix. Wherein, the configuration of the cross matrix information can be flexible, which can be accomplished either by the cross chip 102, or by a Field Programmable Gate Array (FPGA). The present invention can greatly reduce the load of the processor in a large capacity cross-connection application environment, which makes the advantages of the present invention more prominent. In addition, the present invention has been applied to practical chip designs, and has been verified by system test.

Above descriptions are only to illustrate preferred embodiments of the present invention but not to limit the present invention. The scope defined in claims shall comprise any modification, equivalent substitution, improvement etc. within the spirit and principle of the present invention.

1. A method for self-routing in synchronous digital cross-connection, comprising:
A. self-routing transmitting means inserting a cross-connection control memory, CM, data into a STM-N data stream according to a frame header indicator and a self-routing start address signal;
B. self-routing receiving means extracting the CM data from the STM-N data stream according to the frame header indicator and the self-routing start address signal; and
C. the self-routing receiving means writing the CM data into a cross-connection control memory.

2. The method according to claim 1, wherein:
Step A further comprises:
the self-routing transmitting means performing cyclic redundancy check, CRC, on the CM data to be inserted into the STM-N data stream to obtain a first check value, and inserting the first check value into the STM-N data stream;
Step B further comprises: the self-routing receiving means extracting the first check value from the STM-N data stream;
Step C is:
the self-routing receiving means performing CRC check on the CM data extracted from the STM-N data stream to obtain a second check value, and comparing the second check value with the first check value extracted from the STM-N data stream: if the second check value is the same as the first check value, the CM data will be written into the cross-connection control memory; otherwise, the CM data will not be written into the cross-connection control memory.

3. The method according to claim 1, wherein:
Step A further comprises:
the self-routing transmitting means setting a configuration allowance signal, and inserting the configuration allowance signal into the STM-N data stream;
Step B further comprises: the self-routing receiving means extracting the configuration allowance signal from the STM-N data stream;
Step C is:
the self-routing receiving means analyzing the configuration allowance signal extracted from the STM-N data stream, and if the configuration allowance signal is valid, the CM data will be written into the cross-connection control memory; otherwise, the CM data will not be written into the cross-connection control memory.

4. The method according to claim 1, wherein, prior to Step A, the method further comprises:
the self-routing transmitting means setting self-routing parameters which comprise a self-routing insertion position; and
the self-routing transmitting means inserting the CM data into the STM-N data stream according to the self-routing insertion position.

5. The method according to claim 4, wherein:
the self-routing parameters further comprising a self-routing configuration page change request indicator;
the cross-connection control memory comprising an active page and an inactive page; and
the self-routing receiving means switching between the active page and the inactive page according to the self-routing configuration page change request indicator, and writing the CM data into the inactive page.

6. A system for self-routing in synchronous digital cross-connection, comprising:
self-routing transmitting means, configured to insert a cross-connection control memory, CM, data into a STM-N data stream according to a frame header indicator and a self-routing start address signal; and
self-routing receiving means, configured to extract the CM data from the STM-N data stream according to the frame header indicator and the self-routing start address signal, and to write the CM data into a cross-connection control memory.

7. The system according to claim 6, wherein:
the self-routing transmitting means comprise a self-routing transmitting control unit, a first CRC checking unit and an inserting data generating unit, wherein,
the first CRC checking unit is configured to perform CRC check on the CM data to be inserted into the STM-N data stream to obtain a first check value; and
the inserting data generating unit is configured to insert the first check value and the CM data into the STM-N data stream under the control of the self-routing transmitting control unit;
the self-routing receiving means comprise a self-routing extracting control unit, a second CRC checking unit and a cross-connection control memory, wherein,
the second CRC checking unit is configured to perform CRC check on the CM data extracted from the STM-N data stream to obtain a second check value, and to compare the second check value with the first check value extracted from the STM-N data stream: if the second check value is the same as the first check value, the self-routing extracting control unit will write the CM data into the cross-connection control memory; otherwise, the self-routing extracting control unit will not write the CM data into the cross-connection control memory.

8. The system according to claim 7, wherein:
the self-routing transmitting control unit is configured to set a configuration allowance signal, and the inserting data generating unit is configured to insert the configuration allowance signal into the STM-N data stream; and
the self-routing extracting control unit is configured to analyze the configuration allowance signal extracted from the STM-N data stream, and if the configuration allowance signal is valid, the CM data will be written into the cross-connection control memory; otherwise, the CM data will not be written into the cross-connection control memory.

9. A self-routing transmitting device in synchronous digital cross-connection, comprising:
a self-routing transmitting control unit, a first CRC checking unit and an inserting data generating unit, wherein,
the first CRC checking unit is configured to perform CRC check on the CM data to be inserted into a STM-N data stream to obtain a first check value, and the inserting data generating unit is configured to insert the first check value and the CM data into the STM-N data stream under the control of the self-routing transmitting control unit.

10. A self-routing receiving device in synchronous digital cross-connection, comprising:
a self-routing extracting control unit, a second CRC checking unit and a cross-connection control memory, wherein,
the self-routing extracting control unit is configured to extract a CM data from a STM-N data stream; the second CRC checking unit is configured to perform CRC check on the CM data to obtain a second check value, and to compare the second check value with a first check value extracted from the STM-N data stream: if the second check value is the same as the first check value, the self-routing extracting control unit will write the CM data into the cross-connection control memory; otherwise, the self-routing extracting control unit will not write the CM data into the cross-connection control memory.
